(19) United States
(12) Patent Application Publication
(10) Pub. No.: US 2024/0341101 A1
(43) Pub. Date: Oct. 10, 2024

(54) SEMICONDUCTOR DEVICE AND METHOD FOR TRANSISTOR MEMORY ELEMENT

(71) Applicant: Tokyo Electron Limited, Tokyo (JP)

(72) Inventors: Mark I. Gardner, Cedar Creek, TX (US); H. Jim Fulford, Marianna, FL (US)

(21) Appl. No.: 18/599,495

(22) Filed: Mar. 8, 2024

Related U.S. Application Data
(60) Provisional application No. 63/457,731, filed on Apr. 6, 2023.

(51) Int. Cl. H10B 51/30; H01L 29/66; H01L 29/78

(52) U.S. Cl. CPC H10B 51/30; H01L 29/66553; H01L 29/6684; H01L 29/78391

(57) ABSTRACT

Methods and devices are described for electronic devices, such as memory elements. In some implementations, the device may include a first layer including a source region, a drain region and a channel between the source region and drain region, the source and drain being in the same or different plane than at least a portion of the channel. In addition, the device may include a gate dielectric on the first layer and in contact with the channel, a first conductor on the gate dielectric, a ferroelectric layer on the first conductor, and a second conductor material on the ferroelectric layer. The gate structure may be utilized as a storage capacitor for a memory element.

### CROSS REFERENCE TO RELATED APPLICATIONS

The present application claims the benefit of U.S. Provisional Application 63/457,731 filed on Apr. 6, 2023, which is incorporated herein in its entirety.

### FIELD OF THE INVENTION

The disclosure relates to microelectronic devices including semiconductor devices, transistors, and integrated circuits, including methods of microfabrication.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

3D integration, i.e., the vertical stacking of multiple devices, aims to overcome scaling limitations experienced in planar devices by increasing transistor density in volume rather than area. Described herein are devices and techniques that enable device stacking and increased device density. Process improvements are also described herein.

In one general aspect, a device may include a first layer including a source region, a drain region and a channel between the source region and drain region. The device may also include a gate structure having a sidewall and bottom surface, the gate structure including: a first conductive layer, a second conductive layer, a ferroelectric material between the first and second conductive layers, and a gate dielectric between the first conductive layer and the channel.

Implementations may include one or more of the following features. A device where the first layer extends along the sidewall and the bottom surface of the gate structure. A device where the gate structure further may include a dielectric spacer between the sidewall of the gate structure and the first layer. A device configured to be maintained in an on state. A device configured to be maintained in an off state. The first layer may include a semiconductive oxide. The gate structure may be configured to operate as a memory element. A plurality of devices as described herein may be arranged in at least one of a vertical or horizontal array. Each device may include a conductive plane having contacts for the source region, drain region and gate region, the contacts arranged along a surface that is coplanar with a surface of the conductive plane abutting the gate structure. Moreover, the source and drain may have a surface that is coplanar with a surface of the gate structure.

In one general aspect, a method may include forming a first layer including a source region, a drain region and a channel between the source region and drain region, the source and drain being in a different plane than at least a portion of the channel. The method may also include forming a gate dielectric on the first layer and in contact with the channel. The method may furthermore include forming a first conductor on the gate dielectric. The method may in addition include forming a ferroelectric layer on the first conductor and a second conductor material on the ferroelectric layer.

Implementations may include forming a dielectric layer and forming an opening in the dielectric layer, the opening having sidewalls and a bottom, and where the first layer of a device is conformally formed at least along the sidewalls and bottom of the opening. The method may include forming a spacer after forming the first layer and before forming the gate dielectric, such that the spacer separates a sidewall of the first layer from a sidewall of the gate dielectric.

The method may be used to form a first memory element. The method may include forming at least one second memory element over the first memory element to form a stack of memory elements. The second memory element may be formed over the first memory element by bonding the first memory element to the at least one second memory element.

A second memory element may be formed by forming a second layer including a source region, a drain region and a channel between the source region and drain region, the second layer electrically insulated from the first device, forming a second gate dielectric on the second layer and in contact with the channel in the second layer; forming a third conductive layer on the second gate dielectric; forming a ferroelectric layer on the third conductive layer; and forming a fourth conductive layer on the ferroelectric layer.

It should be noted that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a profile view of a device according to a first implementation.

FIG. 2 illustrates a profile view of a device according to a second implementation.

FIG. 3 illustrates a profile view of a device according to a third implementation.

FIG. 4 illustrates exemplary devices, layouts and alternatives that may be implemented in accordance with the present disclosure.

FIGS. 5-9 illustrate a method of formation of the device according to the first implementation.

FIGS. 10-15 illustrate a method of formation of the device according to the third implementation.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the apparatus in use or operation in addition to the orientation depicted in the figures. The apparatus may be otherwise oriented (rotated 90 degrees or at other orientations) and the spatially relative descriptors used herein may likewise be interpreted accordingly.

Reference throughout the specification to “one embodiment” or “an embodiment” means that a particular feature, structure, material, or characteristic described in connection with the embodiment is included in at least one embodiment, but do not denote that they are present in every embodiment. Thus, the appearances of the phrases “in one embodiment” in various places through the specification are not necessarily referring to the same embodiment. Furthermore, the particular features, structures, materials, or characteristics may be combined in any suitable manner in one or more embodiments.

Embodiments of the disclosure can be described with reference to the figures as follows.

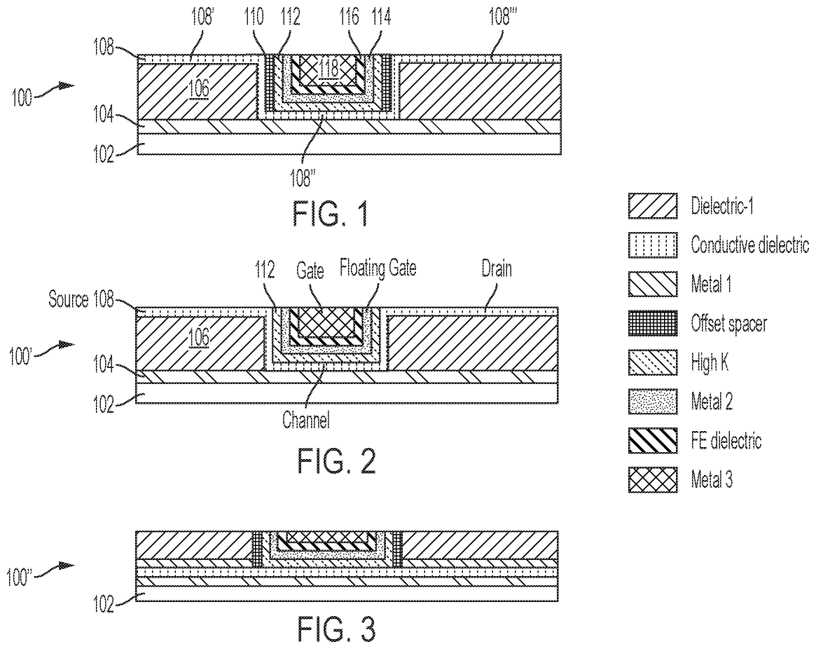

FIG. 1 shows an exemplary semiconductor device (or device) 100 according to some embodiments of the disclosure. The semiconductor device (or device) 100 can include a substrate 102 on which a stack of dielectric layers 104 and 106 are provided. A semiconducting layer 108 is formed in an opening within dielectric layer 106 and includes a source region 108′, a channel region 108″ and drain 108″″.

In some embodiments, the substrate 102 may be a semiconductor substrate such as Si substrate. The substrate 102 may also include other semiconductors such as germanium (Ge), silicon carbide (SiC), silicon germanium (SiGe), or diamond. Alternately, the substrate 102 may include a compound semiconductor, insulator, conductor, and/or an alloy semiconductor. By way of example, in some embodiments, the substrate 102 may also include silicon phosphide (SiP), silicon phosphorus carbide (SiPC), a silicon-on-insulator (SOI) structure, a SiGe-on-SOI structure, a Ge-on-SOI structure, a III-VI materials, or a combination of any of the above materials. The insulating layers can include SiO, SiN, SiC, SiCN, SiCON, SION, or the like. The interconnect layers can include polysilicon, W, Ru, Co, Cu, Al, or the like. Alternatively, the substrate may be an insulator or conducting material.

Layers 104 and 106 may be the same, similar, or different dielectric layers, such as silicon oxide, silicon nitride or other suitable material. Layer 108 may be a semiconductive layer such as a semiconductive behaving oxide, a 2D material, an epitaxial semiconductive behaving material, other suitable material, or combinations thereof. Some examples of N-type semiconductive behaving oxides include In₂O₃, SnO₂, InGaZnO, and ZnO. One example of a P-type conductive channel is SnO. Additionally or alternatively, the channel may comprise a 2D material. Some example 2D materials for use in forming the channel include, but are not limited to, WS₂, WSe₂, WTe₂, MoS₂, MoSe₂, MoTe₂, HfS₂, ZrS₂, and TiS₂, GaSe, InSe, phosphorene, and other similar materials. The materials may be annealed during or after the device formation process to recrystallize or grow the crystals and thereby improve electrical characteristics. For the sake of simplicity, the use of semiconductive behaving oxide will be used to illustrate the device.

Device 100 also includes a dielectric spacer 110 and a gate structure comprised of a gate dielectric 112, a conductive layer 114, a ferroelectric layer 116, and conductive layer 118. Device 100 is particularly useful for a transistor that is typically maintained in an “on” state with current present in the channel when the device is not programmed. The device 100 may function as a transistor with a variable threshold voltage in different regions of the circuit due to amount of charge programed to the floating gate. Additionally or alternatively, device 100 may be configured to be utilized as a memory element.

The upper surfaces of the semiconductive layer, dielectric layer, and gate structure define a plane upon which a conductive plane may be formed. The conductive plane includes contacts for the source region, drain region and gate region.

The device according to claim 1 wherein the source and drain have a surface that is coplanar with a surface of the gate structure.

FIG. 2 shows an alternative in which the dielectric spacer is omitted and the gate dielectric is formed on the semiconductive layer 108. Device 100 is particularly useful for a transistor that is typically maintained in an “off” state with current not present in the channel when the device is not programmed.

FIG. 3 illustrates a device formed according to similar techniques described but in which the source, drain, and channel regions all lie in essentially the same plane.

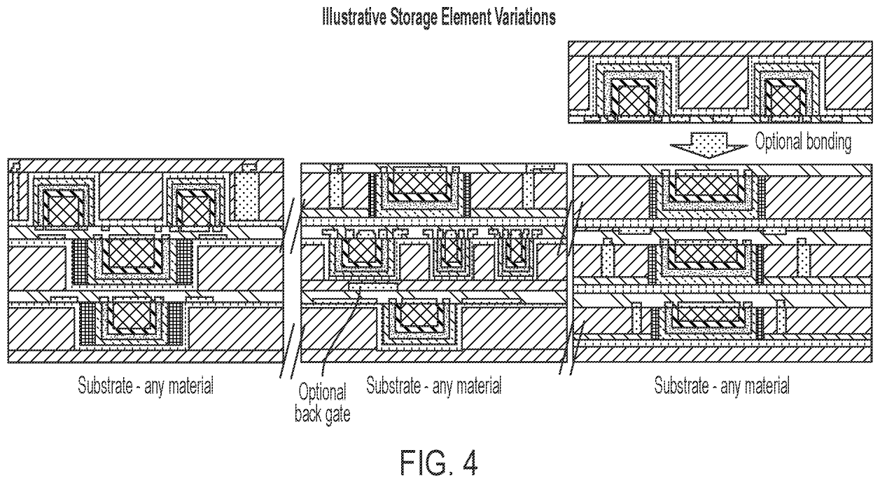

FIG. 4 illustrates exemplary devices, layouts and alternatives that may be implemented in accordance with the present disclosure.

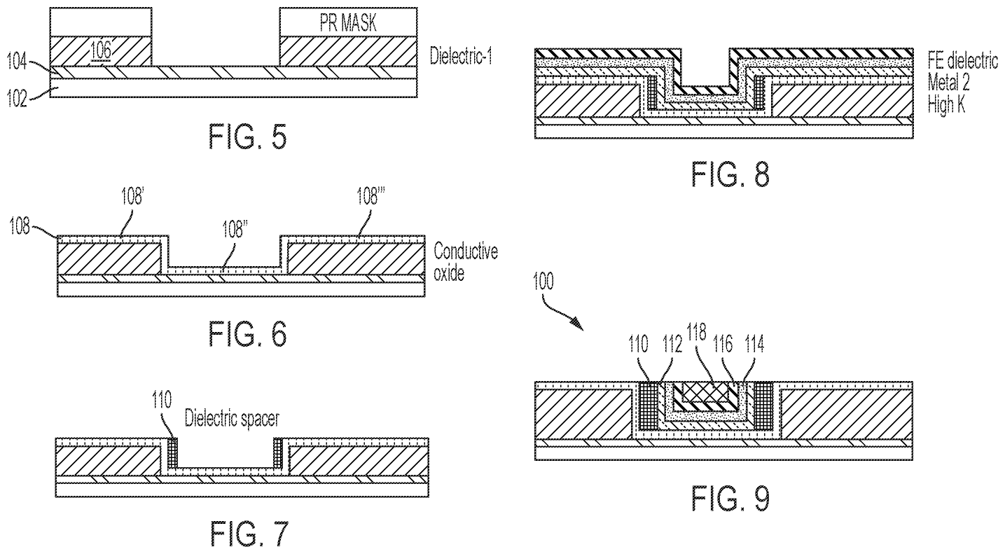

FIGS. 5-9 illustrate a method for forming device 100 that generally includes forming a dielectric layer with an opening; and forming a transistor with a gate structure self-aligned to source, drain and channel regions. Of course, other steps and/or similar devices and/or other circuitry may be formed that is not shown, but such details are omitted for the sake of clarity and brevity. According to one example, a method includes providing a substrate 102 with a dielectric layer 104. In the case where substrate 102 is a conductive material or semiconductor material, such as Si, GaAs, layer 104 may provide isolation of the substrate from overlying layers. Alternatively, the substrate 102 may be a dielectric, which may avoid the need for dielectric 104, in which case it may be omitted.

As shown in FIG. 5, dielectric 106 maybe provided and may be patterned using a photoresist (PR) mask and a removal step such as a plasma assisted etch.

As shown in FIG. 6, the PR mask may be removed and a first layer 108, such as a semiconductive oxide, may be formed with areas designated for a source region, a drain region and a channel between the source region and drain region. The source and drain may be in a different plane than at least a portion of the channel by virtue of being formed on dielectric layer 106.

As shown in FIG. 7, a dielectric spacer 110 may be formed. If forming the device 100′, shown in FIG. 2, this layer may be omitted.

As shown in FIG. 8, a plurality of layers may then be formed, e.g., by forming a gate dielectric 112 on the first layer 108 and in contact with the channel 108″, forming a first conductor 114 on the gate dielectric, and forming a ferroelectric layer 116 on the first conductor 114.

As shown in FIG. 9, a second conductor material 118 is formed on the ferroelectric layer 116. The device is thereby complete though other steps may be utilized that are not shown for the sake of brevity and simplicity. For example, conductive contacts may be formed and coupled to the source region 108′, the drain region 108′ and the first and second conductors 114 and 118. Additionally, layer 108 may be patterned so as to isolate adjacent devices from each other or other circuit elements. Once formed, additional devices may be formed over device 100, as shown in FIG. 4, to form a system of devices in a circuit or plurality of circuits. Each of these devices may be operated as a logic element, memory element, or combination thereof. Additional elements may be added by bonding them to an upper surface of the resulting structure through direct dielectric-to-dielectric, or hybrid bonding techniques as is known in the art.

A method for forming a second device over the first device 100 may include forming a second layer including a source region, a drain region and a channel between the source region and drain region, the second layer electrically insulated from the first device. The, a second gate dielectric is formed on the second layer and in contact with the channel in the second layer. A third conductive layer is formed on the second gate dielectric. Subsequently, a ferroelectric layer is formed on the third conductive layer; and a fourth conductive layer is formed on the ferroelectric layer. The result is a second device like the first device and either coupled to, or electrically isolated from, the first device.

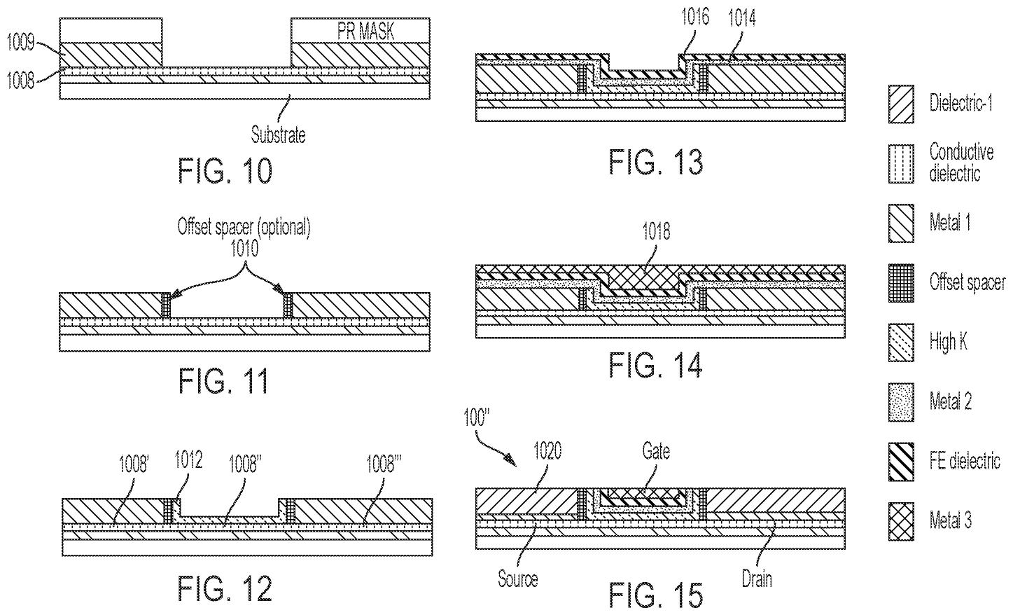

FIGS. 10-15 illustrate an alternative method for forming device 100″ that similarly includes forming a device with a gate structure self-aligned to source, drain and channel regions. The source and drain regions are at least partially outside of the opening in the dielectric and the channel region and the gate structure is at least partially within the opening defined in a dielectric. However in the case of the device 100 or 100′, the source, drain, and channels are formed after forming the dielectric layer with the opening. In the case of device 100″, the source, drain, and channels are formed before forming the dielectric layer with the opening. More particularly, and as shown in FIG. 10, layer 1008, which may be a semiconductive behaving oxide, is formed. A metal layer 1009 may be formed and then patterned using a PR mask.

As shown in FIG. 11, the PR mask is removed and an optional spacer 1010 may be formed.

As shown in FIG. 12, a gate dielectric 1012 is formed on the first layer 1008 and in contact with the channel 108″. A sidewall of gate dielectric 1012 may be in contact with a sidewall of spacer 1010.

As shown in FIG. 13, a first conductor 1014 is formed on the gate dielectric 1012, and a ferroelectric layer 1016 is formed on the first conductor 1014. As shown in FIG. 14, a second conductor material 1018 is formed on the ferroelectric layer 1016. As shown in FIG. 15, a CMP or other planarization technique may remove excess portions of layers 1014, 1016, and 1018. A portion of layer 1009 may be removed and replaced with a dielectric layer 1020 which may allow for isolated vias (not shown) to contact the conductive layer 1009.

The device is thereby complete though other steps may be utilized that are not shown for the sake of brevity and simplicity. For example, conductive contacts may be formed and coupled to the source region 1008′, the drain region 1008′ and the first and second conductors 1014 and 1018. Additionally, layer 1008 may be patterned so as to isolate adjacent devices from each other or other circuit elements. Once formed, additional devices may be formed over device 100″, as shown in FIG. 4, to form a system of devices in a circuit or plurality of circuits. Each of these devices may be operated as a logic element, memory element, or combination thereof. Additional elements may be added by bonding them to an upper surface of the resulting structure through direct dielectric-to-dielectric, or hybrid bonding techniques as is known in the art.

What has been described and illustrated herein is an example along with some of its variations. The terms, descriptions and figures used herein are set forth by way of illustration only and are not meant as limitations. Many variations are possible within the spirit and scope of the subject matter, which is intended to be defined by the following claims—and their equivalents—in which all terms are meant in their broadest reasonable sense unless otherwise indicated.

What is claimed is:

1. A device comprising:
a first layer including a source region, a drain region and a channel between the source region and drain region; and
a gate structure having a sidewall and bottom surface, the gate structure including:
a first conductive layer,
a second conductive layer,
a ferroelectric material between the first and second conductive layers, and
a gate dielectric between the first conductive layer and the channel.

2. The device of claim 1 wherein the first layer extends along the sidewall and the bottom surface of the gate structure.

3. The device of claim 2 wherein the gate structure further comprises a dielectric spacer between the sidewall of the gate structure and the first layer.

4. The device of claim 2 wherein the device is configured to be maintained in an off state.

5. The device of claim 3 wherein the device is configured to be maintained in an on state.

6. The device of claim 1 wherein the first layer comprises a semiconductive oxide.

7. The device of claim 1 wherein the gate structure is configured to operate as a memory element.

8. A plurality of devices according to claim 1 wherein the plurality of devices are arranged in at least one of a vertical or horizontal array.

9. The device according to claim 1 further comprising a conductive plane comprising contacts for the source region, drain region and gate region, the contacts arranged along a surface that is coplanar with a surface of the conductive plane abutting the gate structure.

10. The device according to claim 1 wherein the source and drain have a surface that is coplanar with a surface of the gate structure.

11. The device according to claim 10, wherein the device is a transistor and the gate structure is a storage element integrated with the transistor.

12. A system comprising a plurality of devices according to claim 1.

13. A method for forming a device comprising:
forming a first layer including a source region, a drain region and a channel between the source region and drain region, the source and drain being in a different plane than at least a portion of the channel;
forming a gate dielectric on the first layer and in contact with the channel;
forming a first conductor on the gate dielectric;
forming a ferroelectric layer on the first conductor; and
forming a second conductor material on the ferroelectric layer.

14. The method of claim 13, wherein prior to forming the first layer, the method further comprises forming a dielectric layer and forming an opening in the dielectric layer, the opening having sidewalls and a bottom, and wherein the first layer is conformally formed at least along the sidewalls and bottom of the opening.

15. The method of claim 13, further comprising forming a spacer after forming the first layer and before forming the gate dielectric, such that the spacer separates a sidewall of the first layer from a sidewall of the gate dielectric.

16. The method of claim 13, wherein the device is a first memory element, the method further comprising forming at least one second memory element over the first memory element to form a stack of memory elements.

17. The method of claim 16, wherein the second memory element is formed over the first memory element by bonding the first memory element to the at least one second memory element.

18. The method of claim 16, wherein the second memory element is formed by a method comprising:
forming a second layer including a source region, a drain region and a channel between the source region and drain region, the second layer electrically insulated from the first device;
forming a second gate dielectric on the second layer and in contact with the channel in the second layer;
forming a third conductive layer on the second gate dielectric;
forming a ferroelectric layer on the third conductive layer; and
forming a fourth conductive layer on the ferroelectric layer.

19. A system comprising a plurality of devices formed according to method of claim 13.

20. A method comprising:
forming a dielectric layer with an opening; and
forming a transistor with a gate structure self-aligned to source, drain and channel regions.

21. The method of claim 20 wherein the source and drain regions are at least partially outside of the opening in the dielectric and the channel region and the gate structure are at least partially within the opening in the dielectric.

22. The method of claim 20 wherein the source, drain, and channels are formed after forming the dielectric layer with the opening.

23. The method of claim 20 wherein the source, drain, and channels are formed before forming the dielectric layer with the opening.
